(19) United States
(12) Patent Application Publication
(10) Pub. No.: US 2008/0315958 A1
(43) Pub. Date: Dec. 25, 2008

(54) PHASE-LOCKED LOOP CIRCUIT, PHASE-LOCKED LOOP CONTROL APPARATUS, AND PHASE-LOCKED LOOP CONTROL METHOD

(75) Inventors: Kyosuke Takahashi, Higashiyamato-shi (JP); Koichi Otake, Yokohama-shi (JP); Daisuke Uchida, Ome-shi (JP); Hideyuki Yamakawa, Kawasaki-shi (JP); Toshihiko Kaneshige, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/124,068

(22) Filed: May 20, 2008

(30) Foreign Application Priority Data
Jun. 25, 2007 (JP) 2007-166634

(51) Int. Cl. H03L 7/00

(52) U.S. Cl. 331/17

(57) ABSTRACT

According to one embodiment, a phase-locked loop circuit comprises a phase difference detection unit which detects a phase error between a reproduced binary data and extracted clock and generates phase error pulse signals each having an amplitude corresponding to the phase error, a phase sifter sensitivity adjusting unit which generates a first adjustment pulse signal produced by adjusting the phase error pulse signal, and a loop filter unit which generates a pulse train signal for feedback control to generate the extracted clock from the first adjustment signal, wherein the phase shifter sensitivity adjusting unit comprises a first pulse doubler unit which generates an expanded pulse signal which doubles a time width of the phase error pulse signal, and a first amplifying unit which amplifies the amplitude of the expanded pulse signal and generates the first adjustment pulse signal.

### CROSS-REFERENCE TO RELATED APPLICATIONS

This application is based upon and claims the benefit of priority from Japanese Patent Application No. 2007-166634, filed Jun. 25, 2007, the entire contents of which are incorporated herein by reference.

### BACKGROUND

1. Field

One embodiment of the invention related to a phase-locked loop (PLL) circuit for use in an optical disk drive etc. More specifically, the invention relates to a digital PLL circuit which performs processing such as a phase comparison and a loop filter.

2. Description of the Related Art

A PLL circuit has been used for transmitting a signal with a frequency in accurate synchronization with a reproduced signal from an optical disk such as a CD and a DVD. In recent years, as progress of digital LSI, a digital PLL circuit has been widely used.

The PLL circuit detects a phase difference between an input signal and an output signal, and generates a signal in synchronization with the input signal by applying feedback control. Therefore, various techniques have been developed so as to generate a synchronous signal with high precision even if the input signal is fluctuated.

The technique disclosed in Jpn. Pat. Appln. KOKAI Publication No. 2004-235858 converts an analog signal into a digital signal to achieve equalization, obtains an effective gain from the equalized data, and absorbs the fluctuations in effective gain by using a reverse characteristic effective gain to be a reverse characteristic of the effective gain.

### BRIEF DESCRIPTION OF THE SEVERAL VIEWS OF THE DRAWINGS

A general architecture that implements the various feature of the invention will now be described with reference to the drawings. The drawings and the associated descriptions are proved to illustrate embodiments of the invention and not to limit the scope of the invention.

FIG. 1 is an exemplary view depicting a part of a configuration of an optical disk reproduction apparatus according to an embodiment of the invention;

FIG. 2 is an exemplary view depicting blocks of a digital PLL circuit according to the embodiment of the invention;

FIG. 3 is an exemplary view depicting a transfer function of the digital PLL circuit according to the embodiment of the invention;

FIG. 4 is an exemplary explanation view depicting a conventional digital PLL circuit according to the embodiment of the invention;

FIG. 5 is an exemplary view depicting a transfer function of the conventional digital PLL circuit according to the embodiment of the invention;

FIG. 6 is an exemplary view depicting frequency characteristics obtained on the basis of each transfer function according to the embodiment of the invention;

FIG. 7 is an exemplary view depicting frequency characteristics obtained on the basis of each transfer function according to the embodiment of the invention;

FIG. 8 is an exemplary view depicting blocks of a digital PLL circuit regarding a first variation according to the embodiment of the invention;

FIG. 9 is am exemplary flowchart explaining an example dynamically switching on/off of a pulse doubler function according to the embodiment of the invention;

FIG. 10 is an exemplary flowchart determining whether or not the pulse doubler function is used in a pulling-in phase according to the embodiment of the invention;

FIG. 11 is an exemplary flowchart depicting blocks of a digital PLL circuit regarding a second variation according to the embodiment of the invention;

FIG. 12 is an exemplary flowchart depicting blocks of a digital PLL circuit regarding a third variation according to the embodiment of the invention;

FIG. 13 is an exemplary flowchart explaining a circuit configuration of a pulse doubler and its signal processing example according to the embodiment of the invention; and

FIG. 14 is an exemplary flowchart explaining a circuit configuration of pulse doubler and its signal processing example according to the embodiment of the invention.

### DETAILED DESCRIPTION

Various embodiments according to the invention will be described hereinafter with reference to the accompanying drawings.

The PLL circuit of the first embodiment of the invention is used, for example, for an optical disk reproduction apparatus.

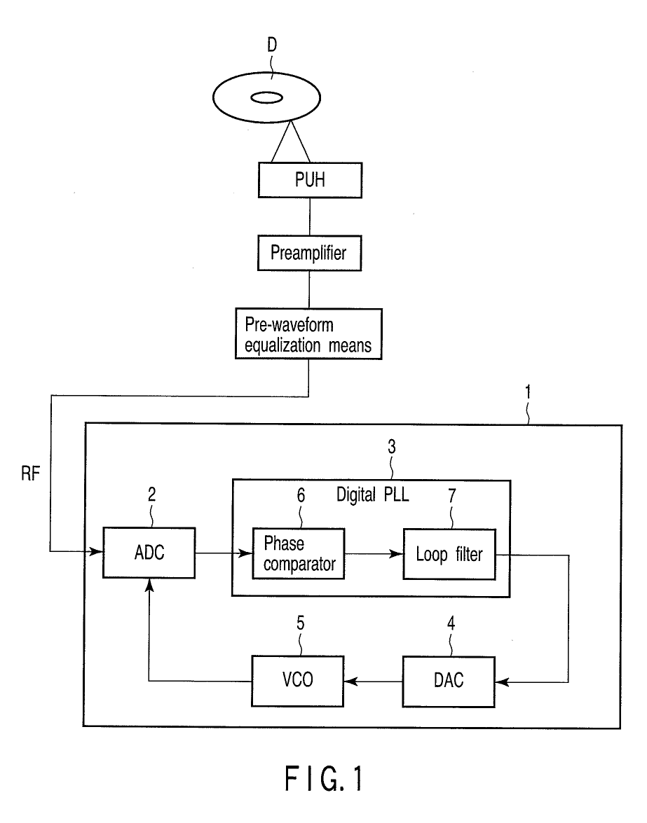

FIG. 1 shows a view illustrating a part of a configuration of an optical disk reproduction apparatus with the invention applied thereto.

In FIG. 1, the reproduction apparatus is an apparatus to read information from an optical disk medium D.

A pick-up head PUH reproduces a signal corresponding to the information recorded on the medium D, and includes a laser light source irradiating laser light to the medium D and a light receiving unit (not depicted) receiving the laser light reflected from the medium D. The reproduced signal output from the light receiving unit is amplified by a preamplifier, further passes though a pre-waveform-equalization unit, and becomes a reproduced RF signal.

Meanwhile, however; the reproduced RF signal is further applied a variety types of processing in a latter stage, a clock signal in synchronization with the reproduced RF signal is needed for processing the reproduced RF signal in the latter stage. To generate the clock signal, the reproduced signal is input to a phase comparison control device 1 equipped with a digital PLL circuit.

The phase comparison control device 1 includes composed of an analog-to-digital converter (ADC) 2, a digital PLL circuit 3, a digital-to-analog converter (DAC) 4 and a voltage control oscillator (VOC) 5. The PLL circuit 3 includes a phase comparator 6 and a loop filter 7.

The ADC 2 samples the reproduced signal synchronously with the clock signal from the VCO 5 to convert the sampled data into a digital RF signal. The phase comparator 6 compares the phase of the digital RF signal with that of the clock signal from the VCO 5 to output a phase error signal PE. The loop filter 7 generates a signal to control the VCO 5 on the basis of the phase error signal PE output from the phase comparator 6. The DAC 4 converts the control signal from the loop filter 7 into an analog signal. The VCO 5 controls the frequency of the clock signal by the analog signal from the DAC 4. The VCO 5 outputs the clock signal to the ADC 2.

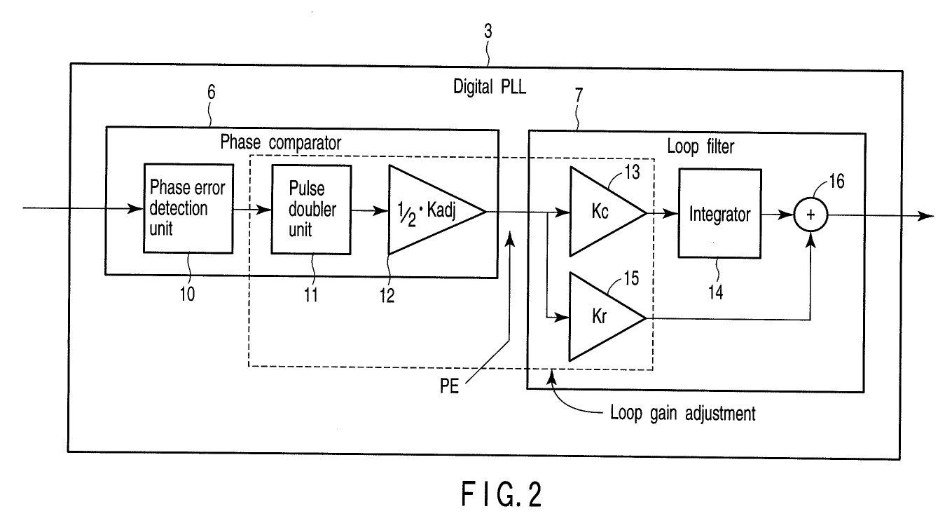

FIG. 2 shows a block diagram of the digital PLL circuit 3 of the first embodiment.

The phase comparator 6 includes a phase error detection unit 10, a pulse doubler unit 11 and a phase shifter sensitivity adjusting unit 12. The loop filter 7 includes a loop filter adjusting unit 13, an integrator 14, a loop filter adjusting unit 15 and an adder 16.

A principle role of the loop filter 7 is to increase a DC gain without changing the gain of a high bandwidth loop of a feedback loop. The loop filter 7 shown in FIG. 2 has loop filter adjusting units 13, 15 having gains G2, G3 for loop filter adjustment as functions to adjust a filter characteristic.

In general, it is supposed that the characteristics of input waves vary according to each kind of optical disks. Therefore, the relationships between the phase error detection values output from each phase error detection unit and the phase differences are not decided uniquely and adjustment is needed in response to situations. Thus, the phase comparator 6 shown in FIG. 2 is provided with the phase shifter sensitivity adjusting unit 12 having a phase shifter sensitivity adjusting gain G1.

The following will describe operations of the digital PLL circuit 3.

The digital RF signal is input in the phase error detection unit 10 of the phase comparator 6. The phase error detection unit 10 compares between the phases of the digital RF signal that is the sample value of the ADC 2 and of the clock signal from the VCO 5 to output the phase error signal PE as a pulse signal. The pulse width (time width) of the output pulse signal is expanded twice by the pulse doubler unit 11. The phase shifter sensitivity adjusting unit 12 amplifies its pulse strength (amplitude).

Here, the adjustment gain G1 of the phase shifter sensitivity adjusting unit 12 is expressed by a formula (1).

G1=1/2×Kadj (1)

Then, the phase error signal PE output from the phase comparator 6 is input in the loop filter 7. The loop filter 7 branches the phase error signal PE into two routes. The pulse strength (amplitude) of one branched phase error signal PE is amplified by the loop filter adjusting unit 13, and after this, the amplified error signal PE is input in the integrator 14. Here, the adjustment gain G2 of the loop filter adjusting unit 13 is expressed by a formula (2).

G2=Kc (2)

The phase error signal PE is converted into a control signal corresponding to an integral operation (I operation) by passing through the aforementioned route.

The pulse strength (amplitude) of the other phase error signal PE is amplified by the loop filter adjusting unit 15. Here, the adjustment gain G3 of the loop filter adjusting unit 15 is expressed by a formula (3).

G3=Kr (3)

The phase error signal PE is converted into a control signal corresponding to a proportional operation (P operation) by passing through the aforementioned route.

The two control signals are added by the adder 16 to be a control signal for the VCO 5 and output from the digital PLL circuit 3.

Like this, the phase comparison control device using the digital PLL circuit 3 of the embodiment controls the phase error by means of PI (proportional and integral operation) control.

While the digital PLL circuit 3 in FIG. 2 has depicted so that the phase shifter sensitivity adjusting unit 12 is disposed inside the phase comparator 6, the invention is not limited to the specific details and representative embodiments, the phase shifter sensitivity adjusting unit 12 may be combined with the loop filter adjusting units 13, 15 of the loop filter 7 in a latter stage. Of course, the order of the phase shifter sensitivity adjusting unit 12 and the pulse doubler unit 11 maybe reversed.

The phase comparator 6 may adapts well known various phase error detection systems. For instance, a system which performs feedback control so that the amplitude at a crossing point becomes just zero by detecting a zero-cross phase, a system which controls the feedback so as to intersect with a zero level at a just intermediate point of sampling points, and a system which obtains a phase error from inclination to an equalization error at a viterbi-decoding input time point depending on a viterbi-decoding result may be adapted to the phase comparator 6.

Further, while FIG. 2 has illustrated an aspect to adjust the loop gain of the feedback loop by the phase shifter sensitivity adjusting gain G1 and the gains G2, G3 for the loop filter adjustment, the invention is not limited to the embodiment, a gain adjusting unit etc. for the input signal may add to the preceding stage of the phase error detection unit 10 and use the adjusting unit for adjustment of the loop gain.

A response characteristic of the digital PLL circuit 3 of the embodiment will be described hereinafter.

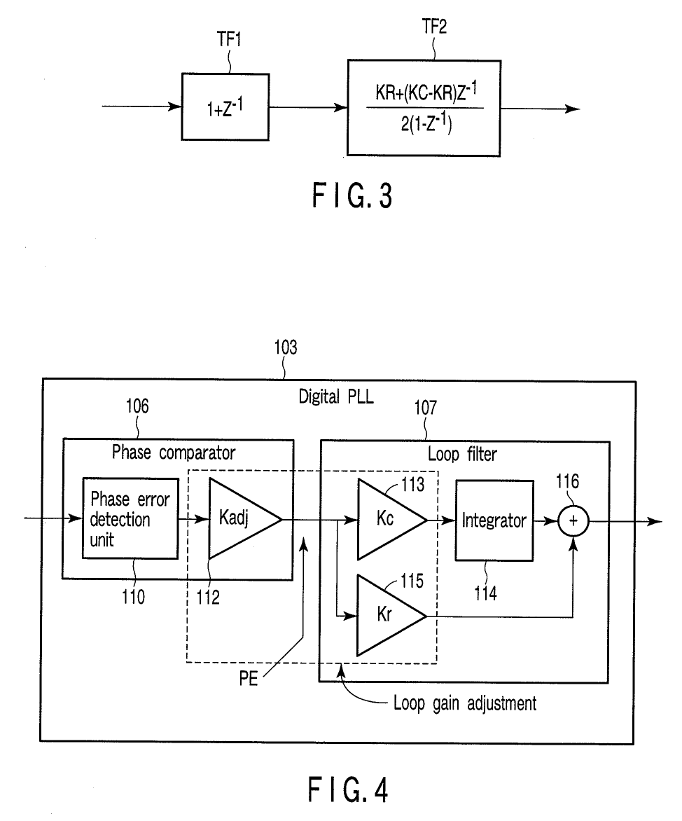

FIG. 3 shows a view illustrating a transfer function of the digital PLL circuit 3 of the embodiment. In the PLL circuit 3, the transfer function is expressed by Z conversion in order to treat an input and out put signal in a discrete-time. The Z conversion is an analysis method corresponding to Laplace transform treating the input and output signal in a consecutive-time.

A transfer function TF1 at a first term expresses the transfer function of the pulse doubler unit 11. Since the pulse signal has a time width over two sampling periods as a result of pulse doubling, an element (Z⁻¹) indicating that the pulse signal is a pulse which is past by one sampling period is added.

A transfer function TF2 at a second term expresses a composite transfer function of the phase shifter sensitivity adjustment unit 12, the loop filter adjusting unit 13, the integrator 14, the loop filter adjusting unit 15 and the adder 16.

A composite transfer function Tfi of the loop filter adjusting unit 13 and the integrator 14 is expressed by a formula (4).

$$\begin{matrix}Tfi = Kc ( {Z}^{- 1} + {Z}^{- 2} + {Z}^{- 3} + {Z}^{- 4} + … ) \\ = Kc \times {Z}^{- 1} / ( 1 - {Z}^{- 1} )\end{matrix} \qquad ( 4 )$$

Accordingly, a composite transfer function Tfpi of the loop filter 7 with the loop filter adjusting unit 15 and the adder 16 added therein is expressed by a formula (5).

Tfpi=Kr+Kc×Z⁻¹/(1−Z⁻¹) (5)

When a constant KC and a constant KR are defined by the formulas (6), (7), respectively, the transfer function FF2 is expressed by a formula (8).

KC=Kc×Kadj (6)

KR=Kr×Kadj (7)

TF2=1/2×KR+1/2×KC×Z⁻¹/(1−Z⁻¹) (8)

FIG. 4 shows a block diagram illustrating a configuration of a conventional digital PLL circuit 103. The conventional PLL circuit 103 is configured so as to correspond to the digital PLL circuit 3 of the embodiment in order to clear the contrast therebetween.

The conventional PLL circuit 103 includes the phase comparator 106 and the loop filter 107. The phase comparator 106 is provided with the phase error detection unit 110 and the phase shifter sensitivity adjusting unit 12. The Loop filter 107 includes a loop filter adjusting unit 113, an integrator 114, a loop filter adjusting unit 115 and an adder 116.

As compared with the conventional digital PLL circuit 103, the digital PLL circuit 3 of the embodiment differs in newly having a pulse doubler unit 11 and in reducing by half the adjustment gain of the phase shifter sensitivity adjusting unit 12.

In other words, the PLL circuit 3 of the embodiment is configured to add a function of expanding the phase comparator output to be usually pulse-output as the phase shifter sensitivity adjustment to the pulse of a two-pulse width. Since the loop gain may be doubled by the additional function part, even if the adjustment gain of the phase shifter sensitivity adjusting unit 12 is reduced by half, the whole of the PLL circuit 3 may maintain the gain with almost the same level as that of the conventional PLL circuit 103. Since the adjustment gain of the phase shifter sensitivity adjusting unit 12 may be reduced by half, it becomes able to reduce a dynamic range of the input in the loop filter 107.

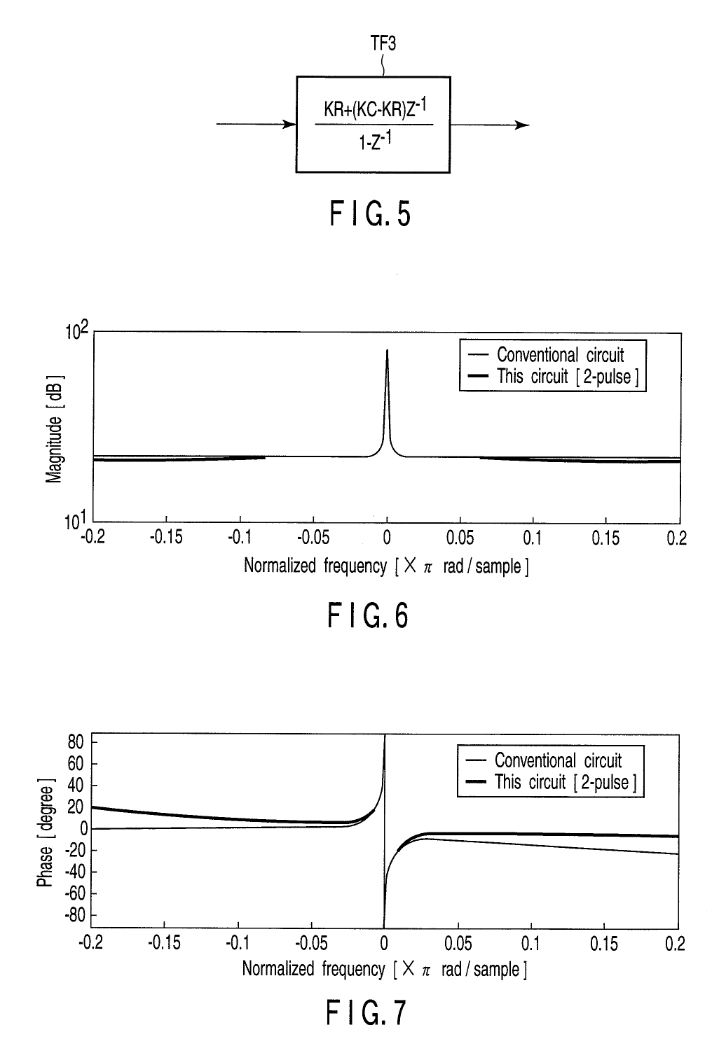

FIG. 5 shows a view illustrating the transfer function of the conventional digital PLL circuit 103.

The transfer function TF3 expresses a composite transfer function of the phase shifter sensitivity adjusting unit 112, the loop filter adjusting unit 113, the integrator 114, the loop filter adjusting unit 115 and the adder 116.

Since each element of the transfer function TF3 uses the same variable identifier as that of the aforementioned transfer function TF2, and the procedure to obtain the transfer function TF3 is the same as that of the aforementioned transfer function TF2, the detailed description thereof will be omitted.

The response performance of the PLL circuit 3 of the embodiment and the conventional PLL circuit 103 will be described. FIGS. 6, 7 depict the frequency characteristics which have been obtained on the basis of each transfer function, respectively.

According to the frequency characteristics, there is no difference in characteristic between the digital PLL circuit 3 and the digital PLL circuit 103 in a band with a low frequency. Namely, in the case in which a band of a control system loop in a band with a sufficiently low frequency in comparison with an operation clock frequency of the ADC 2 that is a sample frequency may be set, both the PLL circuits 3, 103 may realize characteristics substantially equal to each other.

Meanwhile, as the band shifts to a high bandwidth, the characteristic of the digital PLL circuit 3 deteriorates in comparison with that of the conventional digital PLL circuit 103. However, it is incorrect to determine that the digital PLL circuit 3 may not be used in a high bandwidth. As long as the band is within a frequency range to be acceptable for use in a phase comparison control device, the digital PLL circuit 3 may utilize the high bandwidth by trading off with a reduction in dynamic range.

(First Variation)

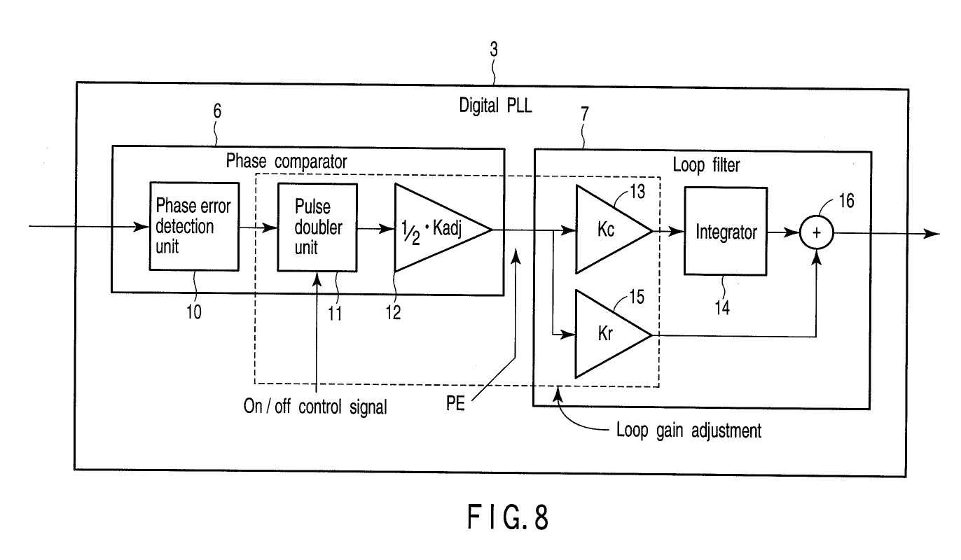

FIG. 8 is a block diagram of a digital PLL circuit 3 regarding a first variation. In the PLL circuit 3, the pulse doubler unit 11 has a function of turning on and off the function of the pulse doubler. The turning on and off of the pulse doubler function is controlled on the basis of an on/off control signal.

The on/off of the pulse doubler function is controlled by an on/off control signal from a host controller disposed in firmware (not shown). The on/off of the pulse doubler function may be configured to be switched by setting, and to be dynamically controlled by the host controller. Hardware may actualize the dynamic switching by using a state machine or the like.

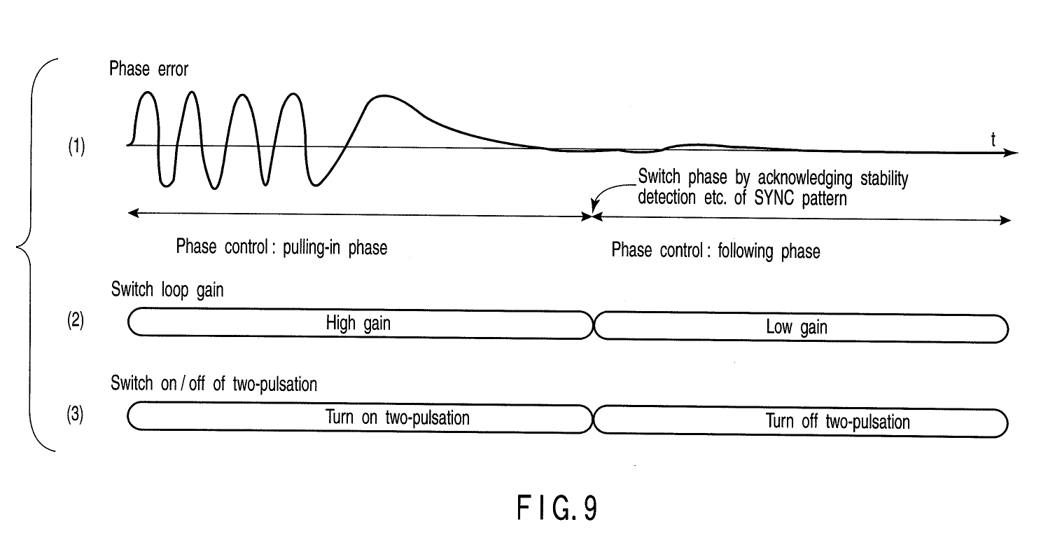

FIG. 9 shows an example of the dynamic switching of on/off of the pulse doubler function.

For processing the reproduced signal from the optical disk, the control method is switched between a phase (pulling-in phase) which emphasizes pulling-in performance and a phase (following phase) which emphasizes following performance such as a reduction in jitter.

In the pulling-in phase, as shown in FIG. 9(1), the phase error varies significantly. Therefore, as shown in FIG. 9(2), in the pulling-in phase, the loop gain is enhanced so as to improve the response. In the following phase the variation in phase error is small, as shown in FIG. 9(2). Therefore, in the following phase, the loop gain is reduced in order to reduce the jitter instead of pursuing the response, as shown in FIG. 9(2).

Thus, as shown in FIG. 9(3), for gain switching in the pulling-in phase and the following phase, to pursue a high gain in response to a need for the pulling-in phase, the loop gain is enhanced by turning on the pulse doubler function. In contrast, in the following phase, the loop gain is switched to a low loop gain by turning off the pulse doubler function. Acknowledging stability detection of a SYNC pattern included in the reproduction wave form executes the switching of the control between the pulling-in phase and the following phase. Using the firmware of the hardware of the state machine may actualize this switching.

The switching control of the pulse doubler function is not limited to the foregoing pulling-in phase and the following phase. In a phase needing a high loop gain, the switching control may enable the use of the pulse doubler function, and in a phase not needing the high loop gain, the switching control may disable the pulse doubler function.

A method of determining whether the pulse doubler function should be enabled or disabled will be described.

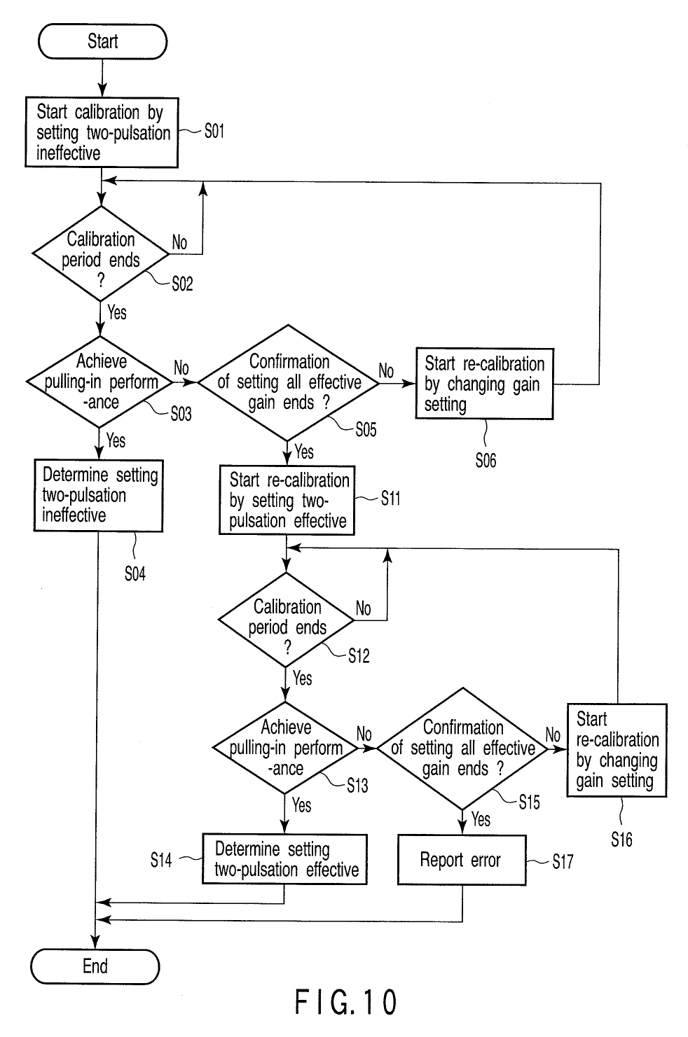

FIG. 10 is a flowchart for determining whether the pulse doubler function should be used or not in the pulling-in phase. A user may determine the use, and the use may be determined automatically in accordance with this flowchart.

In Block S01, the pulling-in phase firstly sets the pulse doubler function disabled to start calibration of the digital PLL circuit 3. Here, the calibration is executed by measuring operations of the PLL circuit 3 under the combination of, for example, a plurality of reproduced signals in the pulling-in phase and a plurality of loop gains.

In Block S02, under the loop gain of a certain level, the calibration of the PLL circuit 3 is executed until a calibration period will end.

If YES in Block S02, namely, the calibration ends under the loop gain of the a certain level, the pulling-in phase checks whether or not the PLL circuit 3 may bring out prescribed performance for the reproduction signal in the pulling-in phase in Block S03.

If YES in Block S03, namely, if the PLL circuit 3 may bring out the prescribed performance, desired performance may be achieved without having to use the pulse doubler function. Therefore, the pulling-in phase decides to set the pulse doubler function ineffective and end the processing in Block S04.

If NO in Block S03, namely, the PLL circuit 3 may not bring out the prescribed performance, the pulling-in phase checks whether or not the calibration is performed for the loop gains of all the levels in Block S05.

If NO in Block S05, namely if there are loop gains which have not been used in the calibration, the setting of the loop gains are changed to start the calibration in Block S06. The pulling-in phase returns to Block S02 to execute the aforementioned Blocks again.

If YES in Block S05, namely, the calibration is executed for the loop gains of all the levels, the pulse doubler function is set effective to start the calibration of the PLL circuit 3 in Block S11. This calibration is executed by measuring operations of the PLL circuit 3 under the combination of the plurality of reproduced signals in the pulling-in phase and the plurality of loop gains as given above.

In Block S12, the pulling-in phase implements the calibration for the PLL circuit 3 under the loop gains of a certain level until the calibration period will end.

If YES in Block S12, namely, the calibration ends under the loop gains in a certain level, the pulling-in phase checks whether or not the PLL circuit 3 may bring out the prescribed performance for the reproduction signal in the pulling-in phase in Block S13.

If YES in Block S13, namely, the PLL circuit 3 may bring out the prescribed performance, the desired performance may be obtained by utilizing the pulse doubler function. Therefore, in Block S14, the pulling-in phase determines to set the pulse doubler function effective and ends the processing.

If NO in Block S13, namely, if the digital PLL circuit 3 may not bring out the prescribed performance, it is checked whether the calibration has been executed for the loop gains of all the levels in Block S15.

If NO in Block S15, namely, there are some loop gains which have not been used in the calibration, the pilling-in phase changes the setting of the loop gains to start the calibration in Block S16. Then, the pulling-in phase returns to Block S12 to start the aforementioned Blocks again.

If NO in Block S15, namely, if the calibration has been executed in the loop gains of all the levels, it is expressed that the desired performance may not be achieved in all the used loop gains. Therefore, the pulling-in phase outputs an error to end the processing.

The given scheme of the calibration in the flowchart may appropriately replace with a procedure to adjust the PLL circuit 3. For instance, the scheme may be replaced by a gain setting procedure in evaluating actual devices or an adjustment procedure in shipping from a factory.

(Second Variation)

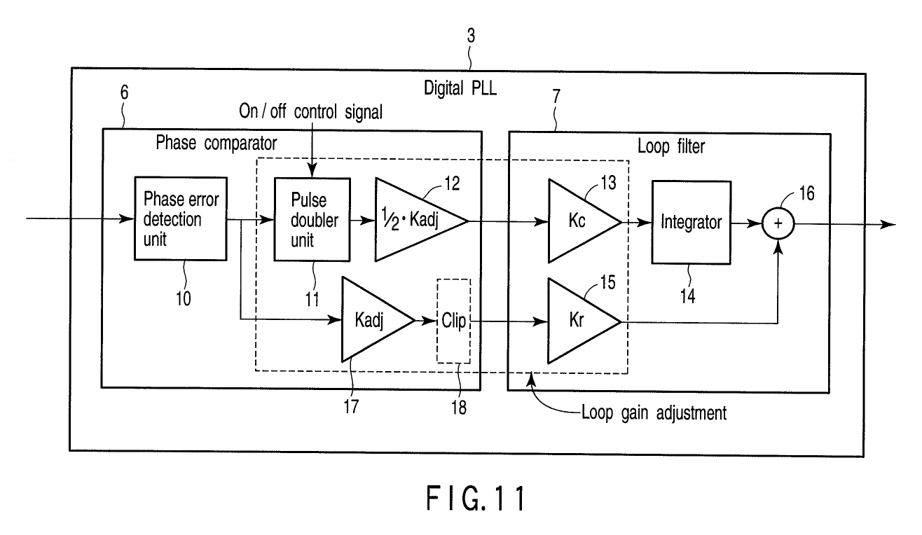

FIG. 11 shows a block diagram of a digital PLL circuit 3 regarding a second variation. The PLL circuit 3 additionally includes a phase shifter sensitivity adjusting unit 17 and a clip unit 18 on a path of proportional term operation in the loop filter 7 in the circuit shown in FIG. 8 regarding the first variation.

Among the frequency characteristics shown in FIGS. 6, 7, if it is supposed a situation in which an influence of phase delay in a high bandwidth, as regards a proportional term, the phase shifter sensitivity adjusting unit 17 having the gain G4 of the phase shifter sensitivity adjustment expressed by the formula (9).

G4=2×G1=Kadj (9)

At this time, the clip unit 18 may be disposed on an output side of the adjusting unit 17. By preventing the control output from becoming larger than a prescribed value to limit a dynamic range, the clip unit 18 guarantees an reduction in a circuit size and an improvement of an operation speed.

(Third Variation)

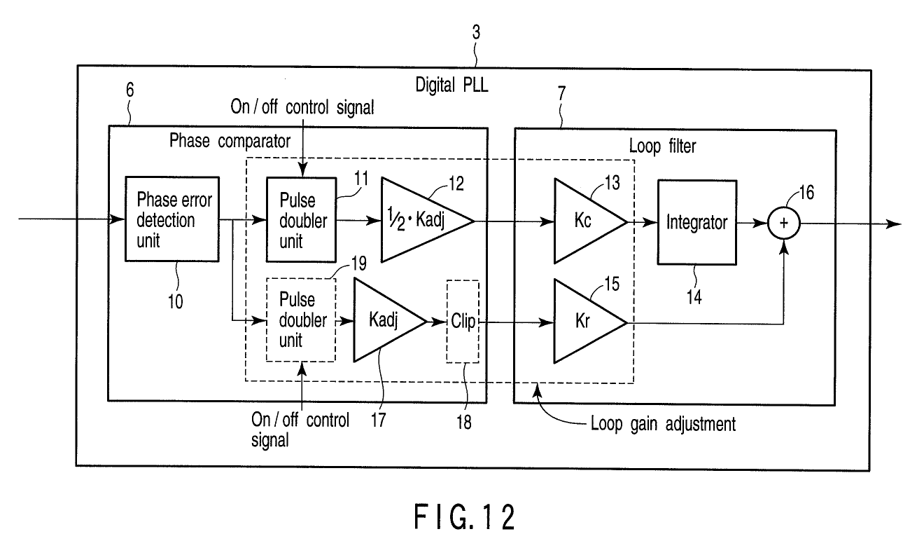

FIG. 12 shows a block diagram of a digital PLL circuit 3 regarding a third variation. The PLL circuit 3 additionally includes the pulse doubler unit 19 on a path of proportional term operation of the loop filter 7 in the circuit shown in FIG. 11 regarding the second variation. In the pulse doubler unit 19, on/off of the pulse doubler function is controlled by other on/off control signals.

Ordinarily, the path of the proportional term is used in the off of the pulse doubler function, and when an influence occurs by limiting the dynamic range of the proportional term of clip processing etc. in setting a high gain, the pulse doubler function is tuned on and the PLL circuit 3 tries to set a gain by half. In this case, the PLL circuit 3 is brought in trade-off between an influence of suppression on upper and lower limit values caused by clipping and an influence of phase delay caused by pulse doubling; however the PLL circuit 3 may select the case of achieving larger performance.

The pulse doubling processing will be described in detail.

For realizing the pulse doubling, there is a need to consider the case in which original phase error output pulses generate consecutively, as a result of continuous detection of phase errors. Here, it is assumed that a system which uses a value close to zero when ADC sample values crosses zero as a phase error detection value for a phase error detection system.

Continuous phase error detection is performed in the case in which the frequency error of the clock for reproduction is large to the reproduced wave form of the optical disk. Ordinarily, the frequency of the clock for reproduction is controlled and the control operation of the PLL is executed after the frequency error of the PLL is made so small as to fall into a capture range of the PLL.

Then, although zero cross generates by two clocks for reproduction, the continuous phase error detection is limited to the case in which the error detection has been processed in a situation of existence of some frequency errors. In other words, the continuous phase error detection is limited to the case in which the zero cross generates to the wave form part of the shortest period 2 T in the reproduced wave forms and the case in which the frequency of the clock for reproduction is low. Since this generation frequency is low, there is little possibility of elicitation of the continuous phase error detection as a performance difference without having to configure the pulse doubler processing unit by strictly taking the case of phase error detection is performed consecutively.

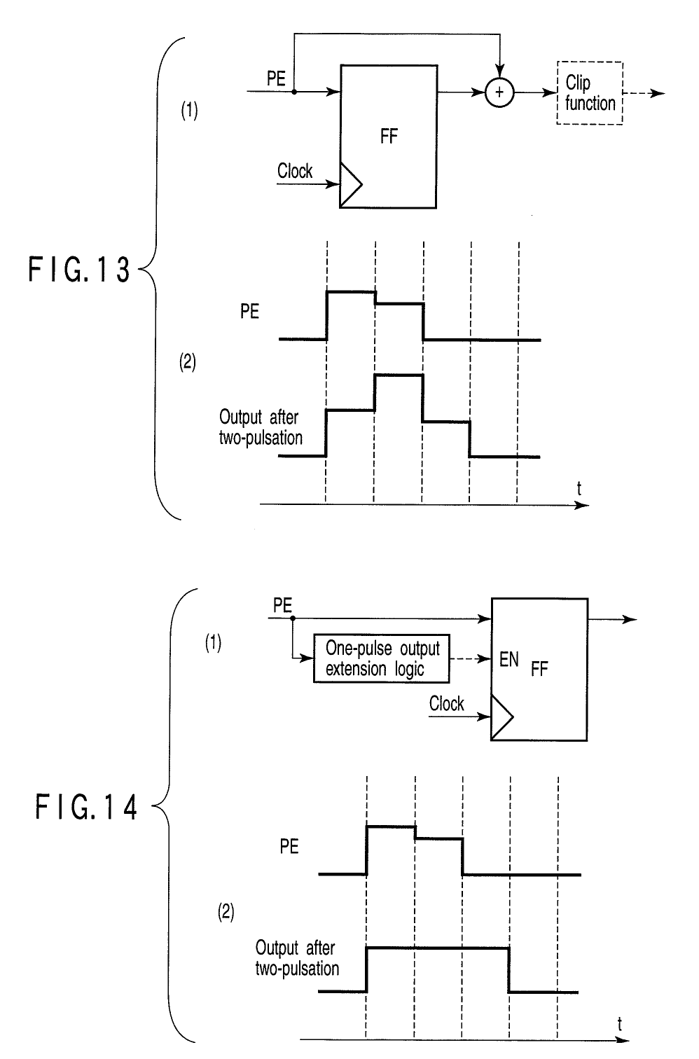

FIG. 13(1) shows a circuit configuration of the pulse doubler, and FIG. 13(2) shows its signal processing example.

In the pulse doubler circuit outputs an addition result for a part at which detection value outputs are overlapped by pulse doubling. Therefore, a clip circuit may be disposed in order to limit the dynamic rage of the phase error output.

FIG. 14(1) shows another circuit configuration of the pulse doubler, and FIG. 14(2) shows an example of its signal processing.

The pulse doubler circuit makes one-pulse extension, and outputs the first pulse output to extend to the sequence number+one pulse in the case when the pulses has sequence numbers.

Further, a variety of variations as pulse doubler circuits are possible approaches.

For instance, only the first pulse of the sequential pulses may be processed. The feedback control of the detection error in the case of detection for a short period may not be performed.

It is our intention that the invention be not limited to the specific details and representative embodiments shown and described herein, and in an implementation phase, this invention may be embodied in various forms without departing from the spirit or scope of the general inventive concept thereof. Various types of the invention can be formed by appropriately combining a plurality of constituent elements disclosed in the foregoing embodiments. Some of the elements, for example, may be omitted from the whole of the constituent elements shown in the embodiments mentioned above. Further, the constituent elements over different embodiments may be appropriately combined.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A phase-locked loop circuit comprising:
a phase difference detection unit configured to detect a phase error between reproduced binary data and an extracted clock signal, and to generate a phase error pulse signal having an amplitude corresponding to the phase error;
a phase shifter sensitivity adjusting unit configured to generate a first adjustment pulse signal produced by adjusting the phase error pulse signal; and
a loop filter unit configured to generate a pulse train signal for feedback control to generate the extracted clock signal based on the first adjustment signal, wherein
the phase shifter sensitivity adjusting unit comprises:
a first pulse doubler unit configured to generate an expanded pulse signal which doubles a time width of the phase error pulse signal; and
a first amplifying unit configured to amplify an amplitude of the expanded pulse signal and to generate the first adjustment pulse signal.

2. The phase-locked loop circuit of claim 1, wherein the loop filter unit comprises a control signal computing unit configured to apply proportional and integral control operations to the first adjustment pulse signal and to generate the pulse train signal for the feedback control.

3. The phase-locked loop circuit of claim 1, wherein the first pulse doubler unit comprises a function switching unit configured to activate and deactivate a function of generating the expanded pulse signal on the basis of an external signal.

4. The phase-locked loop circuit of claim 1, wherein a gain of the first amplifying unit of the phase shifter sensitivity adjusting unit is approximately one half of the gain in a case in which the first pulse doubler unit is not activated.

5. The phase-locked loop circuit of claim 1, wherein the first pulse doubler unit is configured to output a first input pulse signal as an expanded pulse signal of a time width of the sequence number plus one pulse when the phase error pulse signal is input consecutively.

6. The phase-locked loop circuit of claim 1, wherein the phase shifter sensitivity adjusting unit further comprises a second amplifying unit configured to amplify the amplitude of the phase error pulse signal and to generate a second adjustment pulse signal, and wherein the loop filter unit is configured to generate a pulse train signal for feedback control to generate the extracted clock based on the first and the second adjustment signals.

7. The phase-locked loop circuit of claim 1, wherein the phase shifter sensitivity adjusting unit further comprises:
a second pulse doubler unit configured to generate a second expanded pulse signal doubling a time width of the phase error pulse signal; and
a second amplifying unit configured to amplify the amplitude of the second expanded pulse signal and to generate a second adjustment pulse signal,
wherein the loop filter unit is configured to generate a pulse train signal for feedback control to generate the extracted clock based on the first and the second adjustment signals.

8. A phase-locked loop control apparatus comprising:
a phase difference detection unit configured to detect a phase error between reproduced binary data and an extracted clock signal, and to generate a phase error pulse signal having an amplitude corresponding to the phase error;
a phase shifter sensitivity adjusting unit configured to generate an adjustment pulse signal produced by adjusting the phase error pulse signal;
a loop filter unit configured to generate a pulse train signal for feedback control to generate the extracted clock based on the adjustment signal;
a digital-to-analog conversion unit configured to convert the pulse train signal for the feedback control into an analog control signal; and
a voltage control oscillation unit configured to convert a frequency of the extracted clock signal in response to the analog control signal, wherein
the phase shifter sensitivity adjusting unit comprises:
a pulse doubler unit configured to generate an expanded pulse signal doubling a time width of the phase error pulse signal; and
an amplifying unit configured to amplify an amplitude of the expanded pulse signal and to generate the adjustment pulse signal.

9. The phase-locked loop control apparatus of claim 8, wherein the reproduced binary data comprises a digital radio frequency signal which is generated by applying analog-to-digital conversion to a reproduced radio frequency signal from an optical disc.

10. A phase-locked loop control method comprising:
detecting a phase error between reproduced binary data and an extracted clock signal to generate a phase error pulse signal having an amplitude corresponding to the phase error;
adjusting the phase error pulse signal to generate an expanded pulse signal which doubles a time width of the phase error pulse signal;
amplifying an amplitude of the expanded pulse signal to generate an adjustment pulse signal; and
generating a pulse train signal for feedback control to generate the extracted clock signal from the adjustment pulse signal.
